(19) United States
(12) Patent Application Publication
(10) Pub. No.: US 2022/0041931 A1
(43) Pub. Date: Feb. 10, 2022

(54) Silicon Etching Liquid

(71) Applicant: Tokuyama Corporation, Yamaguchi (JP)

(72) Inventors: Manami Oshio, Yamaguchi (JP); Seiji Tono, Yamaguchi (JP); Yoshiki Seike, Yamaguchi (JP)

(73) Assignee: Tokuyama Corporation, Yamaguchi (JP)

(21) Appl. No.: 17/414,370

(22) PCT Filed: Dec. 9, 2019
(86) PCT No.: PCT/JP2019/048150

§ 371 Date: Jun. 16, 2021

(30) Foreign Application Priority Data
Dec. 18, 2018 (JP) 2018-236342

(51) Int. Cl. C09K 13/00; H01L 21/306

(52) U.S. Cl. CPC C09K 13/00; H01L 21/30604

(57) ABSTRACT

An etching solution contains a quaternary ammonium compound as a main component, by which an etching rate for silicon is improved, no adhered substances are formed on an etching surface during etching, and the etching rate does not decrease even after continuous use for a long time. The silicon etching solution contains a phenol compound represented by the following Formula (1), a quaternary ammonium compound, and water, and has a pH of 12.5 or more.

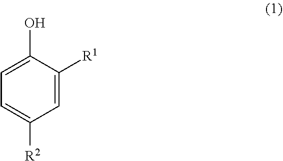

wherein R¹ is a hydrogen atom, a hydroxy group, an alkyl group, an alkoxy group, or an amino group. R² is a hydrogen atom, a hydroxy group, an alkoxy group, or an amino group. R¹ and R² are not hydrogen atoms at the same time. When R¹ is a hydrogen atom, R² is not a hydroxy group. When R¹ is an alkyl group or a hydroxy group, R² is not a hydrogen atom.

### TECHNICAL FIELD

The present invention relates to a silicon etching solution used in surface processing and etching steps when manufacturing various silicon devices.

### BACKGROUND ART

Silicon has been applied to various fields by utilizing excellent mechanical properties, and electrical properties including a low resistance, relatively high stability compared with other metals, and less restrictions on a post-treatment thereof. By utilizing the mechanical properties, silicon has been applied to valves, nozzles, printer heads, and semiconductor sensors for detecting various physical quantities such as a flow rate, a pressure, and an acceleration (for example, a diaphragm of a semiconductor pressure sensor or a cantilever of a semiconductor acceleration sensor). By utilizing the electrical properties, silicon has been applied to various devices as a material for a part of a metal wiring, a gate electrode, and the like. Such various silicon devices are required to be highly integrated, miniaturized, highly sensitive, and highly functional depending on applications thereof. In order to satisfy these requirements, a fine processing technique is used in manufacturing these silicon devices.

As silicon surface processing and etching, wet etching such as isotropic silicon etching using nitrohydrofluoric acid, and anisotropic etching using an aqueous solution of a well-known alkaline chemical such as KOH, hydrazine, or tetramethylammonium hydroxide (hereinafter abbreviated as TMAH) are proposed (see Patent Literatures 1 and 2).

Since the etching using nitrohydrofluoric acid can isotropically etch silicon regardless of a crystal orientation thereof, single crystal silicon, polysilicon, and amorphous silicon can be uniformly etched. However, there are problems that there is no etching selectivity between silicon and a silicon oxide film, and it is easy to undercut and side etch a mask. The etching selectivity is a ratio of an etching property to a target substance to an etching property to other members. When only the target substance is etched and other members are not etched, it is said that “the etching selectivity is high”. Therefore, “there is no etching selectivity between silicon and a silicon oxide film” means that both silicon and the silicon oxide film are etched in the same manner.

In alkaline etching, silicon has a property that an etching rate differs by 100 times depending on the crystal orientation. Therefore, it is possible to make a silicon device having a complicated three-dimensional structure from a single crystal silicon by utilizing this etching anisotropy. For example, a silicon device can be manufactured by putting a silicon wafer in which a portion that should not be etched is masked with a silicon oxide film or a silicon nitride film into an etching tank, in which an etching solution is introduced, to dissolve unnecessary portions of the silicon wafer. Although the crystal anisotropy property cannot be used for polysilicon and amorphous silicon, the alkaline etching has been used in various semiconductor processes by utilizing a property of a high etching selectivity between silicon and the silicon oxide film. Among alkaline chemicals, KOH and TMAH, which have low toxicity and are easy to handle, are preferably used alone.

Among these alkaline chemicals, TMAH has an etching rate for a silicon oxide film that is almost as low as one order of magnitude than that in the case of using KOH, so that TMAH has such an advantage that a silicon oxide film cheaper than a silicon nitride film can be used as a mask material (see non-Patent Literature 1). Although TMAH has such an advantage, TMAH also has a disadvantage of low production efficiency since an etching rate for silicon is slower than that of KOH. Therefore, a method of adding a specific additive has been proposed as a method for increasing the etching rate of TMAH against silicon (see Patent Literatures 3 and 4). For example, in Patent Literature 3, the etching rate is increased by adding a reducing compound including at least one selected from hydroxylamines, hypophosphates, reducing saccharides, ascorbic acid, brentscatechin, and derivatives thereof. In Patent Literature 4, the etching rate is improved by adding at least one compound selected from the group consisting of iron, iron (III) chloride, iron (II) hydroxide, nickel (II) hydroxide, nickel, hydroxylamine, dimethylamine, N,N-diethylhydroxylamine, ethylenediamine, isopropanolamine, benzylamine, 2-ethoxyethylamine, ammonium fluoride, ammonium iodide, ammonium thiosulfate, ammonium thiocyanate, ascorbic acid, L-cysteine, pyridine, quinolinol, oxalic acid, catechol, hydroquinone, benzoquinone, and guanidine carbonate.

### CITATION LIST

### Patent Literature

Patent Literature 1: JP-A-H09-213676
Patent Literature 2: JP-A-H11-233482
Patent Literature 3: JP-A-2006-054363
Patent Literature 4: JP-A-2006-186329

### Non-Patent Literature

Non-Patent Literature 1: Sensors and Materials, Tabata et al., 2001, Vol. 13, No. 5, p. 273-283

### SUMMARY OF INVENTION

### Technical Problem

The present inventors have evaluated continuous usability of the etching solution in order to investigate practicality of the etching solution containing a quaternary ammonium compound such as TMAH as a main component described in Patent Literatures 3 and 4. As a result, it has been found that the performance differs depending on the type of an additive to be added, and some problems occur. That is, it has been found that (1) in the case of using an etching solution to which amines such as hydroxylamine is added, there is a problem that the etching rate decreases when the etching solution is continuously used for a long time; and (2) in an etching solution in which a metal such as iron or nickel or a salt thereof is added and then the metal is dissolved, the etching rate is improved, but there is a problem that the metal adheres to an inclined portion (silicon (111) plane) of a silicon substrate etched during etching and a step of removing such adhered substances is required after the etching. Therefore, it is meaningful to find an additive having an excellent effect.

Therefore, an object of the present invention is to provide an etching solution containing a quaternary ammonium compound such as TMAH as a main component, by which an etching rate for silicon is improved, no adhered substances are formed on an etching surface during etching, and the etching rate does not decrease even after continuous use for a long time.

### Solution to Problem

The problem of adhered substances is a problem peculiar to the use of metal-based additives, which thus can be avoided by using non-metal-based additives. The problem of decrease in the etching rate is probably due to stability of additives, but it is difficult to unconditionally determine a behavior of an additive in a system since various factors are intertwined.

The present inventors have studied the effects of adding various compounds, and found that by adding a specific compound to an etching solution, an etching rate for silicon is improved, no adhered substances are formed, and a decrease in an etching rate due to continuous use can be prevented. Thus, the present invention has been completed.

That is, the present invention relates to a silicon etching solution containing a phenol compound represented by the following Formula (1), a quaternary ammonium compound, and water, and having a pH of 12.5 or more.

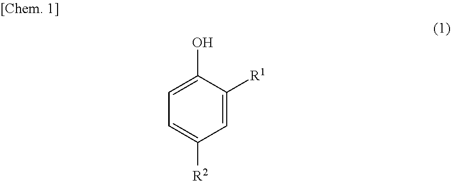

(In this formula, R¹ is a hydrogen atom, a hydroxy group, an alkyl group, an alkoxy group, or an amino group. R² is a hydrogen atom, a hydroxy group, an alkoxy group, or an amino group. R¹ and R² are not hydrogen atoms at the same time. When R¹ is a hydrogen atom, R² is not a hydroxy group. When R¹ is an alkyl group or a hydroxy group, R² is not a hydrogen atom.)

It is preferable that a concentration of the quaternary ammonium compound is 1 mass % to 50 mass %, and a concentration of the phenol compound represented by the Formula (1) is 0.05 mass % to 20 mass %.

Another aspect of the present invention is a method for manufacturing a silicon device, which includes a step of etching a silicon wafer, a polysilicon film, or an amorphous silicon film, in which the etching is performed using the above-mentioned silicon etching solution.

### Advantageous Effects of Invention

By using the etching solution of the present invention, it is possible to perform wet etching for silicon at a high etching rate, and the etching rate does not decrease even if the etching solution is used continuously for a long time. Furthermore, since no metal-based additives are used, no adhered substances are formed on an inclined portion of an etched silicon substrate, and no step of removing metal adhered substances after etching is required.

### DESCRIPTION OF EMBODIMENTS

An etching solution of the present invention contains an aqueous solution of a quaternary ammonium compound. Here, as the quaternary ammonium compound, tetramethylammonium hydroxide (TMAH), tetraethylammonium hydroxide, or tetrabutylammonium hydroxide used in a conventional etching solution formed of an aqueous solution of a quaternary ammonium compound can be used without particular limitation. One type of these quaternary ammonium compounds may be used alone, or a plurality of different types thereof may be mixed and used. Among these quaternary ammonium compounds, it is most preferable to use TMAH because of a high etching rate for silicon. A concentration of the quaternary ammonium compound is not particularly different from conventional etching solutions, and is 1 mass % to 50 mass %, preferably 3 mass % to 30 mass %, and more preferably 3 mass % to 25 mass % based on a total mass of the etching solution. When the concentration is in the range of 1 mass % to 50 mass %, an excellent etching effect can be obtained without causing crystal precipitation.

The etching solution of the present invention is characterized by containing a specific amount of a phenol compound represented by the following Formula (1). By containing the phenol compound, it is possible to improve the etching rate for silicon.

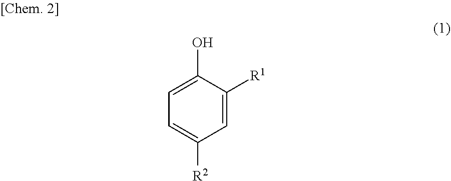

(In the above Formula (1), R¹ is a hydrogen atom, a hydroxy group, an alkyl group, an alkoxy group, or an amino group. R² is a hydrogen atom, a hydroxy group, an alkoxy group, or an amino group. R¹ and R² are not hydrogen atoms at the same time. When R¹ is a hydrogen atom, R² is not a hydroxy group. When R¹ is an alkyl group or a hydroxy group, R² is not a hydrogen atom.)

In R¹ and R², the alkyl group and the alkoxy group each preferably has 1 to 3 carbon atoms, and more preferably 1 to 2 carbon atoms.

R¹ is preferably a hydrogen atom, an alkoxy group, or an alkyl group. R² is preferably a hydroxy group, an alkoxy group, or an amino group. Furthermore, when R¹ is a hydrogen atom, it is preferable that R² is an alkoxy group or an amino group. When R¹ is an alkoxy group or an alkyl group, it is particularly preferable that R² is a hydroxy group.

The phenol compound represented by the above Formula (1), which is particularly preferably used in the present invention, is not specifically shown, but examples thereof include o-methoxyphenol, p-methoxyphenol, p-ethoxyphenol, o-aminophenol, p-aminophenol, methylhydroquinone, and methoxyhydroquinone. Among these compounds, p-methoxyphenol, p-aminophenol, methylhydroquinone, and methoxyhydroquinone are particularly preferred. One type of these phenol compounds may be used alone, or a plurality of different types may be mixed and used.

A preferred content of the phenol compound represented by the above Formula (1) in the etching solution of the present invention differs depending on the type of the phenol compound. In general, a total mass ratio of the phenol compound to the total mass of the etching solution is preferably 0.05 mass % to 20 mass %, and more preferably 0.1 mass % to 10 mass %, and particularly preferably 1 mass % to 5 mass %. In this case, the contents of the phenol compound and the quaternary ammonium compound are adjusted so that pH of the etching solution is 12.5 or more. The pH is preferably 13 or more. When the content of the phenol compound is in the range of 0.05 mass % to 20 mass % and the pH of the etching solution is 12.5 or more, an excellent effect of improving the etching rate for silicon can be obtained. When a concentration of the phenol compound represented by the above Formula (1) is lower than 0.05 mass %, it is difficult to obtain the desired effects, and when the concentration of the phenol compound represented by the above Formula (1) is higher than 20 mass %, the effect of improving the etching rate is reduced. When the pH of the etching solution is less than 12.5, the etching rate may decrease.

The etching solution of the present invention can be easily prepared by adding a predetermined amount of the phenol compound to an aqueous solution of the quaternary ammonium compound having a predetermined concentration and dissolving the phenol compound therein. In this case, instead of directly adding the phenol compound, an aqueous solution of the phenol compound having a predetermined concentration may be prepared in advance and added.

The etching solution of the present invention contains the above phenol compound and quaternary ammonium compound, and the balance is usually water. However, as long as an object of the present invention is not impaired, additives used in the etching solutions in the related art may be blended or silicon may be dissolved therein. A surfactant may be added to improve wettability. For example, any one of a cationic surfactant, a nonionic surfactant, and an anionic surfactant can be used. Alternatively, a decomposition inhibitor for preventing decomposition of additives, an additive or an organic solvent for preventing damage to members other than silicon used for silicon fine processing, or for controlling the etching rate for silicon may be added. It is not preferable that the organic solvent causes discoloring or denaturation after addition, but there is no limitation as long as the etching property can be improved or maintained. Such other additives may be contained in a ratio of 10 mass % or less with respect to the total mass of the etching solution.

The etching solution of the present invention has advantages of a quaternary ammonium compound aqueous solution-based etching solution, namely, that it has low toxicity, is easy to handle, and can realize the use of an inexpensive silicon oxide film as a mask material. The etching solution of the present invention also has advantages of improving the etching rate for silicon when silicon is etched under the same conditions, preventing adhered substances, and preventing a decrease in the etching rate due to continuous use, as compared with conventional quaternary ammonium compound aqueous solution-based etching solutions. Therefore, the etching solution of the present invention can be suitably used as an etching solution when manufacturing various silicon devices, such as processing a valve, a nozzle, a printer head, and a semiconductor sensor (for example, a diaphragm of a semiconductor pressure sensor or a cantilever of a semiconductor acceleration sensor) for detecting various physical quantities such as a flow rate, a pressure, and an acceleration, and etching a polysilicon film or an amorphous silicon film applied to various devices as a material of a part of a metal wiring and a gate electrode, by a wet etching technique for silicon.

When a silicon device is manufactured using the etching solution of the present invention, it is sufficient to perform wet etching for silicon using the etching solution of the present invention. A method in this case is not particularly different from that in the case of using the conventional etching solutions. For example, the method can be preferably performed by putting “a silicon wafer in which a necessary portion of the silicon wafer is masked with a silicon oxide film or a silicon nitride film”, as an object to be etched, into an etching tank into which an etching solution is introduced, and utilizing a chemical reaction with the etching solution to dissolve unnecessary portions of the silicon wafer.

A temperature of the etching solution during etching may be appropriately determined in a range of 20° C. to 95° C., and is preferably in a range of 40° C. to 95° C. in consideration of a desired etching rate, shape and surface condition of silicon after the etching, productivity, and the like.

For the wet etching for silicon, it is sufficient to simply immerse the object to be etched in the etching solution, but an electrochemical etching method of applying a constant potential to the object to be etched can also be adopted.

Examples of the object to be etched in the present invention include silicon single crystal, polysilicon, and amorphous silicon, and the object may contain a silicon oxide film or a silicon nitride film which is a non-object that is not to be etched, and a metal such as aluminum. For example, there may be a structure in which a silicon oxide film or a silicon nitride film, and a metal film are laminated on a silicon single crystal to form a pattern shape, a structure in which polysilicon and a resist are further formed and coated thereon, or a structure in which a metal portion such as aluminum is covered with a protective film and silicon is patterned.

### EXAMPLES

Hereinafter, the present invention will be described in more detail with reference to Examples, but the present invention is not limited to these Examples.

### Examples 1 to 8

Into a fluororesin container having a volume of 60 ml, 20 ml of a 5 mass % TMAH aqueous solution obtained by dissolving various additives shown in Table 1 in a ratio of 2 mass % was introduced, and then the container was heated using a water bath until a liquid temperature reached 80° C.

After the liquid temperature reached 80° C., a small piece of a 1 cm×2 cm silicon wafer was immersed in the above etching solution for 20 seconds, and the etching rate for silicon was measured. The silicon wafer is obtained by forming an oxide film on the silicon wafer using a batchwise thermal oxidation furnace and then forming a polysilicon film of 1 μm (±10%) thereon by a vacuum CVD method. The etching rate was determined by measuring a film thickness of the polysilicon film formed by the vacuum CVD method before etching and after etching with a reflection spectroscopic film thickness meter (F20 film thickness measurement system manufactured by Filmometry), and then dividing a difference in the film thickness by an etching time. The pH of each etching solution was measured when the liquid temperature was 23° C. to 24° C. using a pH meter (a desktop pH meter F-73 manufactured by HORIBA, Ltd.) and a pH electrode (a flat ISFET pH electrode 0040-10D manufactured by HORIBA, Ltd.). Results are shown in Table 1.

When the etched silicon surface was observed by FE-SEM (JSM-7800F Prime manufactured by JEOL, Ltd.), no adhered substances were observed because no metal-based additives were used.

### Examples 9 to 28

The etching rate was determined in the same manner as in Example 1 except that the concentration of TMAH, the types and amounts of additive substances were changed as shown in Table 1. Results are shown in Table 1.

TABLE 1

| | TMAH | | | Etching | |
|---|---|---|---|---|---|
| | con- | | Adding | rate | |
| | centration | Additive | amount | (μm/ | |
| | (mass %) | substance | (mass %) | min) | pH |
| Example 1 | 5 | p-ethoxyphenol | 2 | 1.1 | 13.6 |
| Example 2 | 5 | o-methoxyphenol | 2 | 0.9 | 13.5 |
| Example 3 | 5 | o-aminophenol | 2 | 1.0 | 13.5 |
| Example 4 | 5 | 1,2,4-benzenetriol | 2 | 1.0 | 13.4 |
| Example 5 | 5 | methyl- | 2 | 1.2 | 13.3 |
| | | hydroquinone | | | |
| Example 6 | 5 | methoxy- | 2 | 1.5 | 13.4 |
| | | hydroquinone | | | |
| Example 7 | 5 | p-methoxyphenol | 2 | 1.6 | 13.5 |
| Example 8 | 5 | p-aminophenol | 2 | 1.5 | 13.5 |
| Example 9 | 5 | methoxy- | 0.5 | 1.4 | 13.6 |
| | | hydroquinone | | | |
| Example 10 | 5 | methoxy- | 1 | 1.6 | 13.5 |
| | | hydroquinone | | | |
| Example 11 | 5 | methoxy- | 3 | 0.9 | 13.2 |
| | | hydroquinone | | | |
| Example 12 | 10 | methoxy- | 1 | 1.5 | 13.9 |
| | | hydroquinone | | | |
| Example 13 | 10 | methoxy- | 3 | 1.6 | 13.7 |
| | | hydroquinone | | | |
| Example 14 | 10 | methoxy- | 5 | 1.3 | 13.7 |
| | | hydroquinone | | | |
| Example 15 | 5 | p-methoxyphenol | 0.5 | 1.5 | 13.6 |
| Example 16 | 5 | p-methoxyphenol | 1 | 1.6 | 13.6 |
| Example 17 | 5 | p-methoxyphenol | 3 | 1.6 | 13.5 |
| Example 18 | 5 | p-methoxyphenol | 5 | 1.4 | 13.3 |
| Example 19 | 10 | p-methoxyphenol | 1 | 1.4 | 13.9 |
| Example 20 | 10 | p-methoxyphenol | 3 | 1.4 | 13.9 |
| Example 21 | 10 | p-methoxyphenol | 4 | 1.4 | 13.8 |
| Example 22 | 10 | p-methoxyphenol | 5 | 1.5 | 13.8 |
| Example 23 | 10 | p-methoxyphenol | 10 | 1.4 | 13.7 |
| Example 24 | 10 | p-aminophenol | 1 | 1.4 | 13.9 |
| Example 25 | 10 | p-aminophenol | 3 | 1.4 | 13.8 |
| Example 26 | 10 | p-aminophenol | 4 | 1.6 | 13.7 |
| Example 27 | 10 | p-aminophenol | 5 | 1.5 | 13.7 |
| Example 28 | 10 | p-aminophenol | 10 | 1.1 | 13.6 |

### Examples 29 and 30

These examples are conducted in order to study whether the etching rate decreases by a thermal stability test assuming continuous use for a long time. The etching rate in Examples 6 and 8 were determined by the same method as in Example 1 except that etching was performed after heating etching solutions to temperature of 80° C. for 24 hours in advance. Results are shown in Table 2.

TABLE 2

| | TMAH | | Adding | |
|---|---|---|---|---|
| | concentration | Additive | amount | Etching rate |
| | (mass %) | substance | (mass %) | (μm/min) |
| Example 29 | 5 | methoxy- | 2 | 1.5 |
| | | hydroquinone | | (1.5; Example 6) |
| Example 30 | 5 | p-aminophenol | 2 | 1.6 |
| | | | | (1.5; Example 8) |

### Comparative Examples 1 to 11

The etching rate was determined in the same manner as in Example 1 except that the concentration of TMAH, the types and amounts of additive substances were changed as shown in Table 3. Results are shown in Table 3.

TABLE 3

| | TMAH | | Adding | | |
|---|---|---|---|---|---|
| | concentration | | amount | Etching rate | |
| | (mass %) | Additive substance | (mass %) | (μm/min) | pH |
| Comparative Example 1 | 5 | — | — | 0.8 | 13.6 |
| Comparative Example 2 | 10 | — | — | 0.8 | 14.0 |
| Comparative Example 3 | 5 | m-methoxyphenol | 2 | 0.8 | 13.6 |
| Comparative Example 4 | 5 | p-tert-butylphenol | 2 | 0.3 | 13.6 |
| Comparative Example 5 | 5 | 4-(methylthio)phenol | 2 | 0.8 | 13.5 |
| Comparative Example 6 | 5 | 2,4-xylenol | 2 | 0.7 | 13.5 |
| Comparative Example 7 | 5 | o-cresol | 2 | 0.6 | 13.5 |
| Comparative Example 8 | 5 | m-cresol | 2 | 0.7 | 13.5 |
| Comparative Example 9 | 5 | p-cresol | 2 | 0.8 | 13.6 |
| Comparative Example 10 | 5 | methoxyhydroquinone | 5 | 0.4 | 12.1 |
| Comparative Example 11 | 10 | methoxyhydroquinone | 10 | 0.3 | 12.3 |

As shown in Table 1, when etching solutions formed of a 5 mass % TMAH aqueous solution and a 10 mass % TMAH aqueous solution having a pH of 12.5 or more to which the phenol compound represented by Formula (1) is added are used, the etching rate for silicon is 0.9 μm/min at the lowest and 1.6 μm/min at the highest. As shown in Comparative Examples 1 and 2, since the etching rate for silicon in the 5 mass % TMAH aqueous solution and the 10 mass % TMAH aqueous solution is 0.8 μm/min, it is found that the etching rate is increased 1.1 to 2 times by the addition of the phenol compound represented by the Formula (1).

However, as shown in Comparative Examples 4 to 6 and 9, it can be seen that when R² in the Formula (1) is not a hydrogen atom, a hydroxy group, an alkoxy group, or an amino group but an alkyl group or an alkylthio group, no improvement in the etching rate for silicon is observed, and on the contrary, the etching rate is slower in some cases. As shown in Comparative Example 7, it can be seen that even when R¹ is an alkyl group and R² is a hydrogen atom, no improvement in the etching rate for silicon is observed, and on the contrary, the etching rate is slower in some cases.

As shown in Comparative Examples 10 and 11, it can be seen that when the pH of the etching solution is less than 12.5, the etching rate for silicon is not improved, and conversely, the etching rate is slower.

As shown in Examples 2, 3, 7, and 8, it is found that when substituents on the phenol compound represented by the Formula (1) are at a para position (Examples 7 and 8), the etching rate for silicon is significantly improved as compared with cases of that at an ortho position (Examples 2 and 3). However, as shown in Comparative Examples 3 and 8, when the substituents on the phenol compound represented by the Formula (1) are at a meta position, there is no effect of improving the etching rate for silicon.

As shown in Examples 29 and 30, the etching rates for silicon are 1.5 μm/min and 1.6 μm/min when the etching solutions are used after being heated at a liquid temperature of 80° C. for 24 hours in advance. As shown in Examples 6 and 8, the etching rates for silicon of the etching solutions that have not been heated for a long time are both 1.5 μm/min. Therefore, it can be seen that the etching rates do not decrease due to the long time heating and the thermal stability of the etching solutions is excellent.

1. A silicon etching solution comprising:
a phenol compound represented by the following Formula (1);
a quaternary ammonium compound; and
water, wherein
a pH is 12.5 or more, 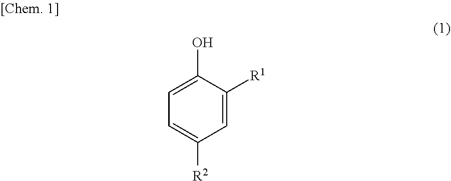
wherein R¹ is a hydrogen atom, a hydroxy group, an alkyl group, an alkoxy group, or an amino group, R² is a hydrogen atom, a hydroxy group, an alkoxy group, or an amino group, R¹ and R² are not hydrogen atoms at the same time, when R¹ is a hydrogen atom, R² is not a hydroxy group, and when R¹ is an alkyl group or a hydroxy group, R² is not a hydrogen atom.

2. The silicon etching solution according to claim 1, wherein a concentration of the quaternary ammonium compound is 1 mass % to 50 mass %, and a concentration of the phenol compound represented by the Formula (1) is 0.05 mass % to 20 mass %.

3. A method for manufacturing a silicon device, comprising:
etching a silicon wafer, a polysilicon film, or an amorphous silicon film, wherein the etching is performed using the silicon etching solution according to claim 1.
